(19) United States
(12) Patent Application Publication
(10) Pub. No.: US 2012/0241862 A1
(43) Pub. Date: Sep. 27, 2012

(54) LDMOS DEVICE AND METHOD FOR MAKING THE SAME

(75) Inventors: Lei Zhang, Chengdu (CN); Yang Xiang, Chengdu (CN)

(73) Assignee: Chengdu Monolithic Power Systems Co., Ltd., Chengdu (CN)

(21) Appl. No.: 13/427,658

(22) Filed: Mar. 22, 2012

(30) Foreign Application Priority Data
Mar. 22, 2011 (CN) 201110077379.2

(51) Int. Cl. H01L 29/78; H01L 21/336

(52) U.S. Cl. 257/339; 438/286; 257/E29.261; 257/E21.417

(57) ABSTRACT

The embodiments of the present disclosure disclose a LDMOS device and the method for making the LDMOS device. The LDMOS device comprises at least one capacitive region formed in the drift region. Each capacitive region comprises a polysilicon layer and a thick oxide layer separating the polysilicon layer from the drift region. The LDMOS device in accordance with the embodiments of the present disclosure can improve the breakdown voltage while a low on-resistance is maintained.

### CROSS-REFERENCE TO RELATED APPLICATION

This application claims the benefit of CN application No. 201110077379.2, filed on Mar. 22, 2011, and incorporated herein by reference.

### TECHNICAL FIELD

The present disclosure relates generally to semiconductor devices, and more particularly but not exclusively to LDMOS devices.

### BACKGROUND

Nowadays, with the development of the semiconductor industry, LDMOS (lateral double-diffused metal oxide semiconductor) devices are used more and more widely.

FIG. 1 illustrates a cross-sectional view of a LDMOS device according to the prior art. The LDMOS device comprises a P-type semiconductor region 11 which may be an inherent part of a substrate or may, for example, be an epitaxial layer. An N-type drift region 12 and a P-type body region 13 both extend from the top surface of the semiconductor region 11 into the semiconductor region 11. An N-type drain region 14 is formed in the drift region 12 proximate to the top surface of the semiconductor region 11. An N-type source region 15 is formed in the body region 13 proximate to the top surface of the semiconductor region 11. A highly doped P-type region may also be formed in the body region 13 as a body contact region. The highly doped P-type region extends from the top surface of the semiconductor region 11 into the body region 13 and is in contact with the source region 15. A gate dielectric layer 16a overlies a portion of the drift region 12, a portion of the body region 13 and a portion of the source region 15. A conductive gate 16b is formed in/on the gate dielectric layer 16a. The LDMOS device may also comprise a field oxide 17 at the top surface of the drift region 12. The field oxide 17 extends laterally from the drain region 14 to the gate dielectric layer 16a. The field oxide 17 is used to reduce the parasitic capacitance of the LDMOS device and also to enhance the gate-to-drain breakdown voltage.

In the LDMOS device, the drift region 12 affects the electric field distribution and can thereby adjust the breakdown voltage and the on-resistance of the LDMOS device. Referring to detail, the length L and the doping concentration C of the drift region 12 are two key factors that affect the breakdown voltage and the on-resistance of the LDMOS device. A longer length or a lower doping concentration results in a higher breakdown voltage and a higher on-resistance. In a LDMOS device, the breakdown voltage and the on-resistance are generally inversely related and the LDMOS device often has a tradeoff between the breakdown voltage and the on-resistance. Thus, how to improve the breakdown voltage while maintaining a low on-resistance becomes a challenge.

### SUMMARY

The present disclosure is directed to a LDMOS device comprising a semiconductor region; a body region formed in the semiconductor region; a drift region formed in the semiconductor region adjacent to the body region; a source region formed in the body region; a drain region formed in the drift region; a gate dielectric layer formed on the semiconductor region adjacent to the body region and the drift region; a conductive gate formed on or in the gate dielectric layer; and at least one capacitive region formed in the drift region. Each of the at least one capacitive region comprises a polysilicon layer and an oxide layer separating the polysilicon layer from the drift region.

### BRIEF DESCRIPTION OF THE DRAWINGS

FIG. 1 illustrates a cross-sectional view of a LDMOS device according to the prior art.

FIG. 2 illustrates a cross-sectional view of a LDMOS device in accordance with one embodiment of the present disclosure.

FIGS. 3A-3E illustrate schematically, in cross-sectional view, manufacturing stages in accordance with one embodiment of the disclosure for fabricating the LDMOS device of FIG. 2.

FIG. 4 illustrates a cross-sectional view of a LDMOS device in accordance with another embodiment of the present disclosure.

FIG. 5 illustrates a cross-sectional view of a LDMOS device in accordance with still another embodiment of the present disclosure.

The use of the same reference label in different drawings indicates the same or like components.

### DETAILED DESCRIPTION

In the present disclosure, numerous specific details are provided, such as examples of circuits, components, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

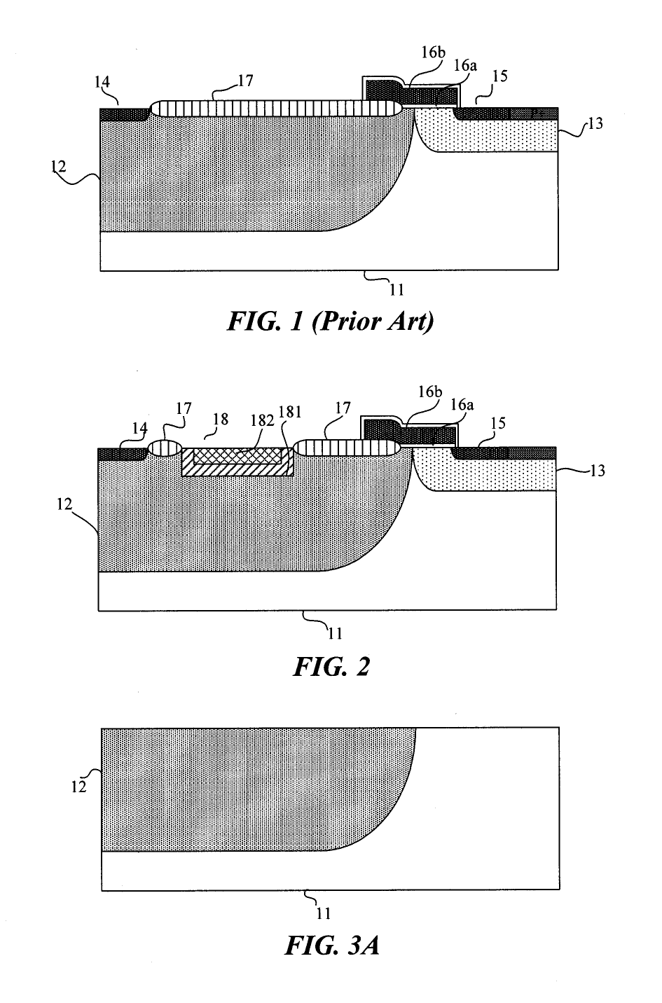

FIG. 2 illustrates a cross-sectional view of a LDMOS device in accordance with one embodiment of the present disclosure. For convenience of description, N-channel LDMOS devices are illustrated, but this is not intended to be limiting and persons of skill in the art will understand that based on the description herein, P-channel LDMOS devices may also be formed by interchanging conductivity types. Compared with the LDMOS device of FIG. 1, a capacitive region 18 is formed between the drain region 14 and the gate dielectric layer 16a and extends from the top surface of the semiconductor region into the drift region 12. The capacitive region 18 comprises a thick oxide layer 181 and a polysilicon layer 182 formed in the thick oxide layer 181. The thick oxide layer 181 separates the polysilicon layer 182 from the drift region 12. The capacitive region 18 and the drift region 12 work as a capacitor with the polysilicon layer 182 and the drift region 12 being the plates and the thick oxide layer 181 being the dielectric.

In operation, the polysilicon layer 182 is biased to a predetermined voltage (e.g., ground) through a contact (not shown) or is floated. The electric field distribution in the drift region 12 is changed due to the capacitive coupling between the polysilicon layer 182 and the drift region 12. Compared with the prior art LDMOS devices, the drift region of the LDMOS device in accordance with one embodiment of the present disclosure can be fully depleted more easily at a low drain voltage.

Under the same length of the drift region and the same drain-to-source voltage, the drift region of the LDMOS device in accordance with one embodiment of the present disclosure can have a higher doping concentration C of the drift region without breaking down the LDMOS device. The on-resistance Rds(on) of the LDMOS device varies with the doping concentration C of the drift region. The higher the doping concentration C is, the lower the on-resistance Rds(on) is. As a result, the LDMOS device in accordance with one embodiment of the present disclosure has a lower on-resistance.

On the other hand, under the same doping concentration C of the drift region and the drain-to-source voltage, the length of the drift region can be made longer to get a higher breakdown voltage in accordance with one embodiment of the present disclosure.

From the description above, the LDMOS device in accordance with one embodiment of the present disclosure solves the problem of the tradeoff between the breakdown voltage and the on-resistance.

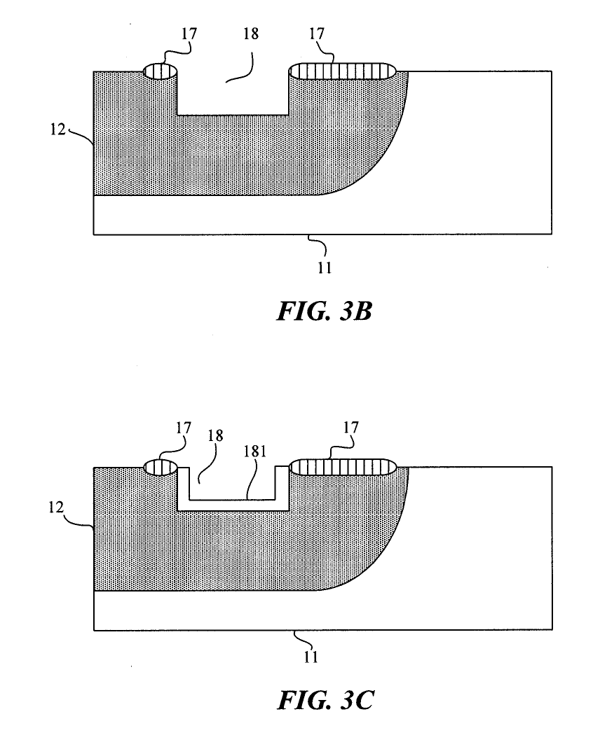

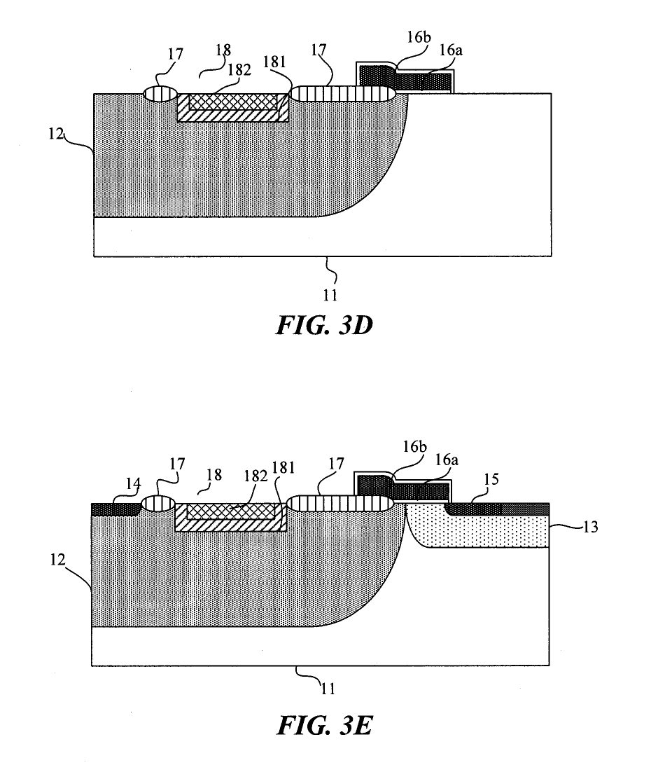

FIGS. 3A-3E illustrate schematically, in cross-sectional view, manufacturing stages in accordance with one embodiment of the disclosure for fabricating the LDMOS device of FIG. 2. For brevity, many conventional steps will only be mentioned briefly herein or will be omitted entirely without providing the well known process details. The LDMOS device structure results from manufacturing stages. The discussion of the various regions that make up the LDMOS device in connection with FIG. 2 and relative doping types is included herein by reference. As noted, the manufacturing stages of FIGS. 3A-3E are, for convenience of explanation and not intended to be limiting, described as for an N-channel device, but persons of skill in the art will understand that by substituting doping of opposite conductivity type for the various regions, P-channel and other types of devices may also be fabricated.

Referring to FIG. 3A, a P-type semiconductor region 11 is provided. The P-type semiconductor region 11 may be an inherent part of a substrate or may, for example, be an epitaxial layer. For convenience of description, it is assumed herein that the semiconductor region 11 is an inherent part of a substrate. A lightly doped N-type drift region 12 is formed in the substrate 11 by, for example, ion implantation and thermal driving-in.

Referring to FIG. 3B, a field oxide 17 is formed at the top surface of the drift region 12 by, for example, growth or deposition. A capacitive region 18 is formed in the drift region 12 by etching.

In manufacturing stage of FIG. 3C, a thick oxide layer 181 is formed in the capacitive region 18 by, for example, growth or deposition.

In manufacturing stage of FIG. 3D, a polysilicon layer 182 is formed in the thick oxide layer 181 by, for example, growth or deposition. Also, a gate dielectric layer 16a with a conductive gate 16b formed therein or thereon is formed on a portion of the field oxide 17, a portion of drift region 12 and a portion of the substrate 11.

In manufacturing stage of FIG. 3E, a P-type body region 13, a drain region 14 and a source region 15 are formed by, for example, ion implantation and thermal driving-in.

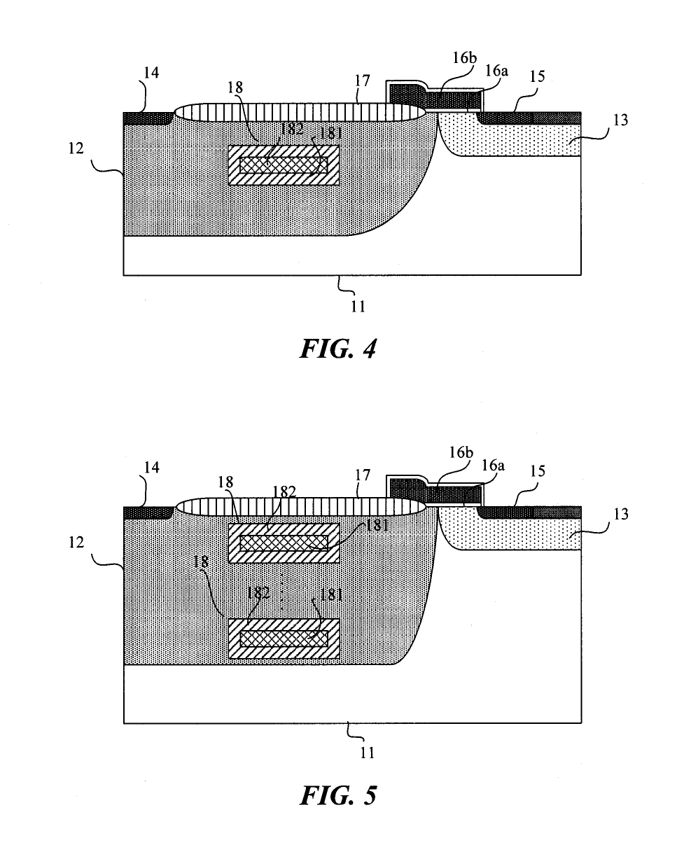

FIG. 4 illustrates a cross-sectional view of a LDMOS device in accordance with another embodiment of the present disclosure. Compared to the LDMOS device of FIG. 2, the capacitive region 18 of the LDMOS device of FIG. 4 is buried in the drift region 12 and under the field oxide 17. The capacitive region 18 comprises a thick oxide layer 181 and a polysilicon layer 182 formed in the thick oxide layer 181. The thick oxide layer 181 separates the polysilicon layer 182 from the drift region 12. The capacitive region 18 and the drift region 12 work as a capacitor with the polysilicon layer 182 and the drift region 12 being the plates and the thick oxide layer 181 being the dielectric. In another embodiment, the field oxide 17 can be removed from the LDMOS device.

In operation, the polysilicon region 182 is biased to a predetermined voltage through conducting vias (not shown) or is floated. An extra depleted region is formed due to the capacitively coupling between the polysilicon region 182 and the drift region 12. The extra depleted region extends upward and downward. Thus, the LDMOS device can be fully depleted more easily at a low drain voltage.

The length L and the depth of the drift region 12 can be optimized so that the drift region 12 can be fully depleted to get a higher doping concentration C of the drift region without breaking down the LDMOS device. As a result, the on-resistance Rds(on) is reduced.

FIG. 5 illustrates a cross-sectional view of a LDMOS device in accordance with still another embodiment of the present disclosure. Compared with the LDMOS device of FIG. 4, the LDMOS device of FIG. 5 comprises a plurality of capacitive regions 18 positioned along a vertical orientation. The capacitive regions 18 have similar structure and work in a similar manner.

In the embodiment of FIG. 5, the capacitive regions 18 are arranged along a vertical position. However, persons of skill in the art will understand that, in other embodiments, the capacitive regions 18 can be arranged in other forms as long as an extra capacitively depleted region is formed in the drift region.

While specific embodiments of the present invention have been provided, it is to be understood that these embodiments are for illustration purposes and not limiting. Many additional embodiments will be apparent to persons of ordinary skill in the art reading this disclosure.

I/We claim:

1. A LDMOS device, comprising:
a semiconductor region having a top surface;
a body region formed in the semiconductor region;
a drift region formed in the semiconductor region adjacent to the body region;
a source region formed in the body region;
a drain region formed in the drift region;
a gate dielectric layer formed on the semiconductor region adjacent to the body region and the drift region;
a conductive gate formed on or in the gate dielectric layer; and
at least one capacitive region formed in the drift region, wherein each of the at least one capacitive region comprises a conductive layer and an dielectric layer separating the conductive layer from the drift region.

2. The LDMOS device of claim 1, wherein the at least one capacitive region comprises a plurality of capacitive regions located along a vertical orientation to the top surface of the semiconductor region.

3. The LDMOS device of claim 1, wherein one of the at least one capacitive region extends from the top surface of the semiconductor region into the drift region.

4. The LDMOS device of claim 1, wherein the at least one capacitive region is buried in the drift region.

5. The LDMOS device of claim 1, wherein the conductive layer of the at least one capacitive region is biased to a predetermined voltage.

6. The LDMOS device of claim 1, wherein the conductive layer of the at least one capacitive region is floated.

7. The LDMOS device of claim 1, wherein the LDMOS device further comprises a field oxide above at least a portion of the drift region.

8. A method of manufacturing a LDMOS device, comprising:
providing a semiconductor region;
forming a drift region in the semiconductor region;
forming a body region in the semiconductor region adjacent to the drift region;
forming a source region in the body region;
forming a drain region in the drift region;
forming a gate dielectric layer on the semiconductor region adjacent to the body region and the drift region;
forming a conductive gate on the gate dielectric layer; and
forming at least one capacitive region in the drift region, wherein each of the at least one capacitive region comprises a conductive layer and an dielectric layer separating the conductive layer from the drift region.

9. The method of claim 8, wherein the step of forming at least one capacitive region comprises forming a plurality of capacitive regions along a vertical orientation.

10. The LDMOS device of claim 8, wherein one of the at least one capacitive region extends from the top surface of the semiconductor region into the drift region.

11. The method of claim 8, wherein the at least one capacitive region is buried in the drift region.

12. The method of claim 8, further comprises biasing the conductive layer of the at least one capacitive region to a predetermined voltage.

13. The method of claim 8, wherein the conductive layer of the at least one capacitive region is floated.

14. The method of claim 8, further comprises forming a field oxide above at least a portion of the drift region.

15. A method of manufacturing a LDMOS device, comprising:
providing a semiconductor region;
forming a drift region in the semiconductor region;
etching the drift region to form a capacitive region;
growing or depositing an dielectric layer in the capacitive region;
depositing and etching to form a conductive layer in the dielectric layer and a conductive gate on the semiconductor region; and
forming a body region, a source region and a drain region in the semiconductor region.

16. The method of claim 15, further comprises biasing the conductive layer of the capacitive region to a predetermined voltage.

17. The method of claim 15, wherein the conductive layer of the capacitive region is floated.

18. The method of claim 15, further comprises growing or depositing a field oxide above at least a portion of the drift region.
